(19) United States
(12) Patent Application Publication
(10) Pub. No.: US 2023/0068016 A1
(43) Pub. Date: Mar. 2, 2023

(54) SYSTEMS AND METHODS FOR ROTATIONAL CALIBRATION OF METROLOGY TOOLS

(71) Applicant: KLA Corporation, Milpitas, CA (US)

(72) Inventors: Alexander Novikov, Kiryat Motzkin (IL); Amnon Manassen, Haifa (IL); Ido Dolev, Manof (IL); Yuri Paskover, Binyamina (IL); Nir Ben David, Hod Hasharon (IL); Yoel Feler, Haifa (IL); Yoram Uziel, Yodfat (IL)

(21) Appl. No.: 17/446,161

(22) Filed: Aug. 26, 2021

(51) Int. Cl. H01L 21/66; G01D 18/00; G01B 21/04

(52) U.S. Cl. CPC H01L 22/12; G01D 18/00; G01B 21/042

(57) ABSTRACT

A system and method for generating an angular calibration factor (ACF) for a metrology tool useful in a fabrication process, the method including providing the metrology tool, the metrology tool including a stage and a housing, measuring a rotational orientation of the stage relative to the housing and generating the ACF for the stage based at least partially on the rotational orientation.

### REFERENCE TO RELATED APPLICATIONS

Reference is hereby made to the following patents and patent applications of the Applicant, which are related to the subject matter of the present application, the disclosures of which are hereby incorporated by reference:
U.S. Pat. No. 7,608,468 entitled APPARATUS AND METHODS FOR DETERMINING OVERLAY AND USES OF SAME;
U.S. Pat. No. 7,804,994 entitled OVERLAY METROLOGY AND CONTROL METHOD;
U.S. Pat. No. 7,876,438 entitled APPARATUS AND METHODS FOR DETERMINING OVERLAY AND USES OF SAME;
U.S. Pat. No. 9,778,213 entitled METROLOGY TOOL WITH COMBINED XRF AND SAXS CAPABILITIES;
U.S. Pat. No. 9,927,718 entitled MULTI-LAYER OVERLAY METROLOGY TARGET AND COMPLIMENTARY OVERLAY METROLOGY MEASUREMENT SYSTEMS;
U.S. Pat. No. 10,527,951 entitled COMPOUND IMAGING METROLOGY TARGETS;
European Patent No. 1,570,232 entitled APPARATUS AND METHODS FOR DETECTING OVERLAY ERRORS USING SCATTEROMETRY;
PCT Application No. PCT/US2019/023918, filed Mar. 25, 2019, and entitled VACUUM HOLD-DOWN APPARATUS FOR FLATTENING BOWED SEMICONDUCTOR WAFERS;
PCT Application No. PCT/US2019/035282, filed Jun. 4, 2019 and entitled MISREGISTRATION MEASUREMENTS USING COMBINED OPTICAL AND ELECTRON BEAM TECHNOLOGY; and
PCT Application No. PCT/US2019/051209, filed Sep. 16, 2019 and entitled PERIODIC SEMICONDUCTOR DEVICE MISREGISTRATION METROLOGY SYSTEM AND METHOD.

### FIELD OF THE INVENTION

The present invention relates to measurement of quality metrics, particularly in the manufacture of semiconductor devices generally.

### BACKGROUND OF THE INVENTION

Various methods and systems are known for measurement of quality metrics, particularly in the manufacture of semiconductor devices.

### SUMMARY OF THE INVENTION

The present invention seeks to provide improved methods and systems for generating an angular calibration factor (ACF) for a metrology tool useful in a fabrication process, the method including providing the metrology tool, the metrology tool including a stage and a housing, measuring a rotational orientation of the stage relative to the housing and generating the ACF for the stage based at least partially on the rotational orientation.

In accordance with an embodiment of the present invention the method also includes positioning a sample within the metrology tool, measuring the sample with the metrology tool, thereby generating at least one output signal, the sample being mounted on the stage and the stage having the rotational orientation during the measurement, and generating at least one quality parameter value of the sample, at least partially based on the ACF and the output signal.

Positioning the sample within the metrology tool can include mounting the sample on the stage and moving the stage relative to the housing.

In accordance with an embodiment of the present invention, the measuring the rotational orientation of the stage includes measuring a rotational orientation of the stage relative to the housing and generating the ACF based at least partially on the rotational orientation.

Measuring the rotational orientation of the stage relative to the housing can include measuring a first linear distance between a first portion of the stage and the housing, measuring a second linear distance between a second portion of the stage and the housing and calculating the rotational orientation of the stage relative to the housing at least partially based on the first linear distance and the second linear distance.

In accordance with an embodiment of the present invention, measuring the at least one site on the sample includes measuring at least one rotationally asymmetric misregistration target formed at the at least one site on the sample.

In accordance with an embodiment of the present invention, the quality parameter is a misregistration between at least a first layer formed on the SDW and a second layer formed on the sample. Alternatively, in accordance with an embodiment of the present invention, the quality parameter is a dimension of at least one feature formed on the sample. Alternatively, in accordance with an embodiment of the present invention, the quality parameter is a dimension of at least one space between features formed on the sample.

There is also provided in accordance with another embodiment of the present invention a system for generating an angular calibration factor (ACF), the system including a metrology tool including a stage and a housing and an angle monitoring sub-system (AMSS) operative to measure a rotational orientation of the stage relative to the housing and to generate the ACF based at least partially on the rotational orientation.

In accordance with an embodiment of the present invention, the angle monitoring sub-system includes at least two radiation transmitter-receiver pairs and at least one radiation reflector. The radiation transmitter-receiver pairs can transmit and receive laser light. In accordance with an embodiment of the present invention, the radiation transmitter-receiver pairs are each fixedly mounted on the stage and the radiation reflector is fixedly mounted on the housing. Alternatively, in accordance with an embodiment of the present invention, the radiation transmitter-receiver pairs are each fixedly mounted on the housing and the radiation reflector is fixedly mounted on the stage.

Alternatively, in accordance with an embodiment of the present invention, the angle monitoring sub-system includes at least two encoders.

In accordance with an embodiment of the present invention, the metrology tool includes the AMSS. Alternatively, in accordance with an embodiment of the present invention, the metrology tool is separate from the AMSS.

The stage can be movable relative to the housing.

The metrology tool can include one of an imaging-based misregistration metrology tool, a scatterometry-based misregistration metrology tool, a critical dimension metrology tool, a shape metrology tool, a film metrology tool, an electron-beam metrology tool and an x-ray-based metrology tool.

In accordance with an embodiment of the present invention, the system also includes a quality parameter generator (QPG), and the AMSS provides the ACF to the QPG.

The QPG can be operative to generate a quality parameter value of the sample based at least partially on the ACF and an output signal of a sample generated by the tool.

In accordance with an embodiment of the present invention, the sample includes a semiconductor device wafer.

There is also provided in accordance with an embodiment of the present invention, for use with the systems or methods of the present invention, a misregistration target useful in calculating a misregistration between at least a first layer formed on the sample and a second layer formed on the sample, the misregistration target being rotationally asymmetric.

### BRIEF DESCRIPTION OF THE DRAWINGS

The present invention will be understood and appreciated more fully from the following detailed description, taken in conjunction with the drawings in which:

FIGS. 1A, 1B and 1C are simplified schematic diagrams of respective first, second and third operative orientations of an embodiment of a metrology system of the present invention; and

FIG. 2 is a simplified flowchart illustrating an embodiment of a method for use with the system of FIGS. 1A-1C.

### DETAILED DESCRIPTION OF THE EMBODIMENTS

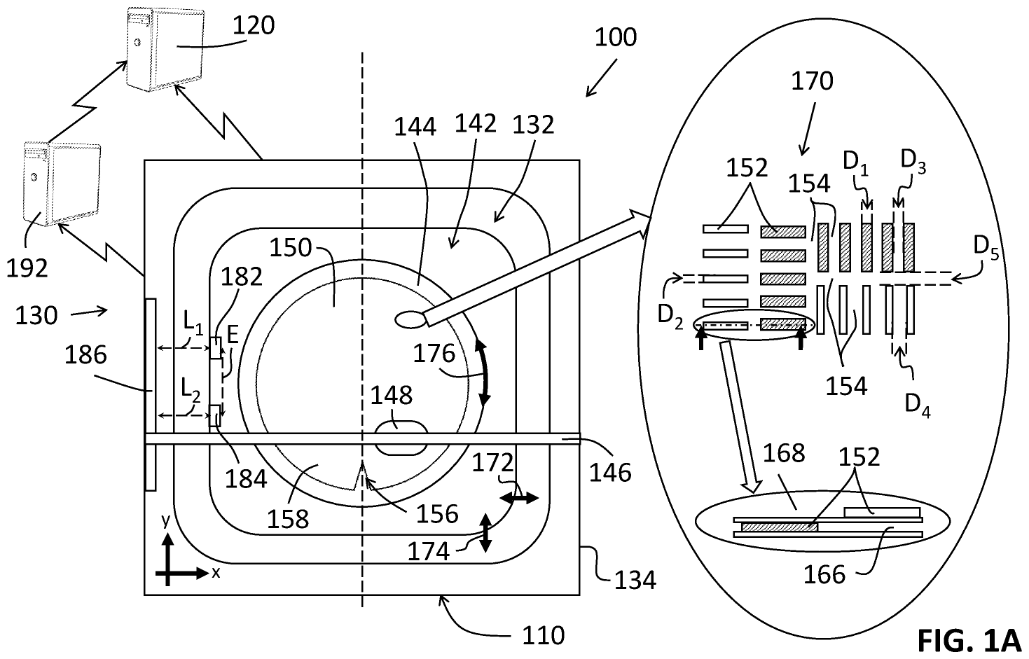

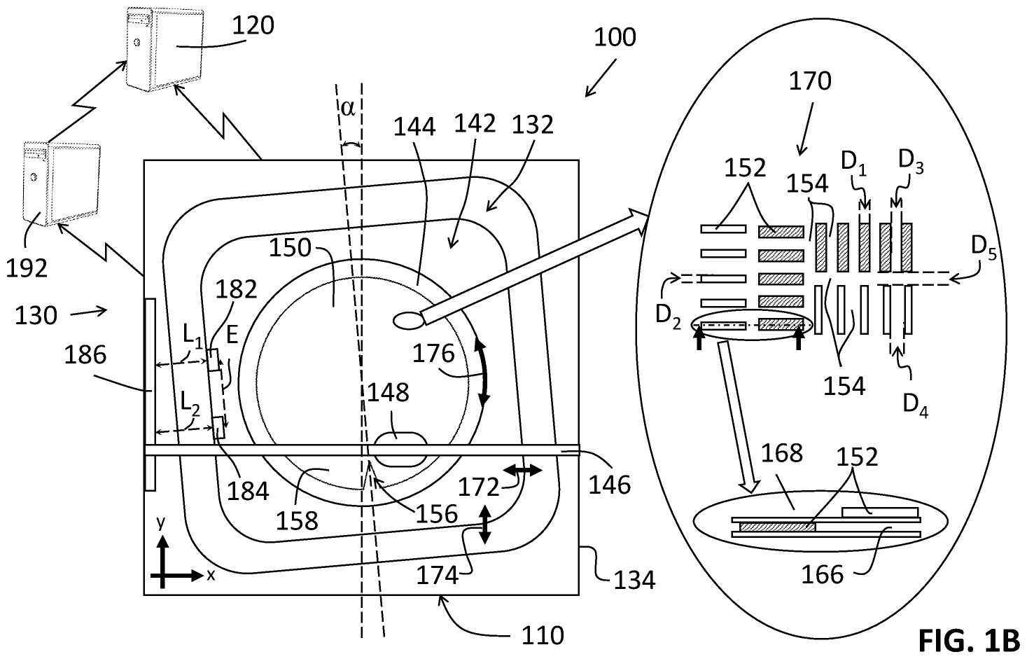

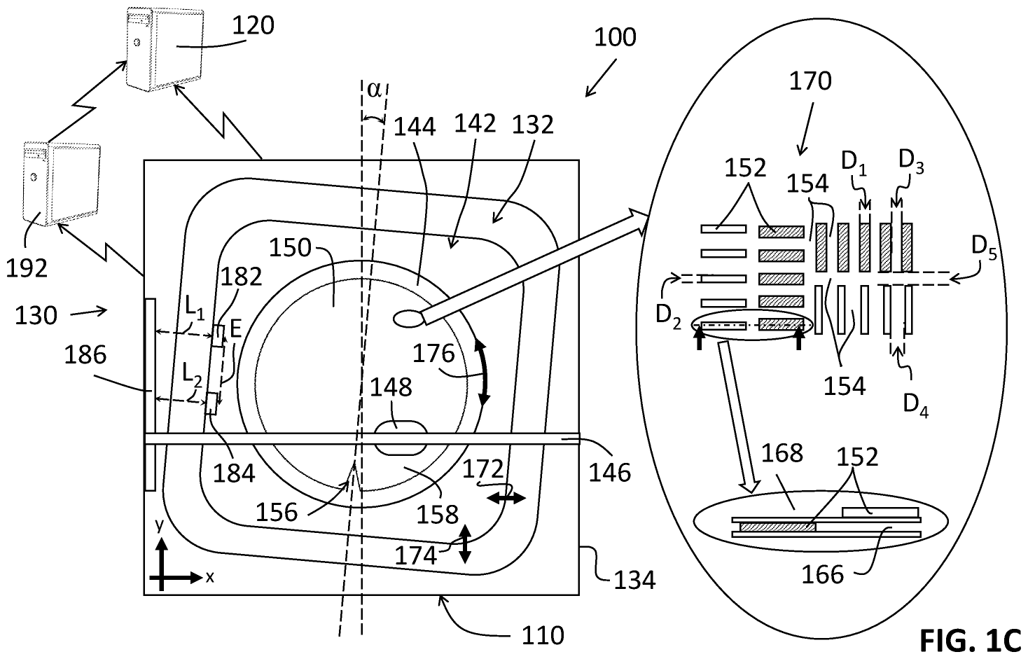

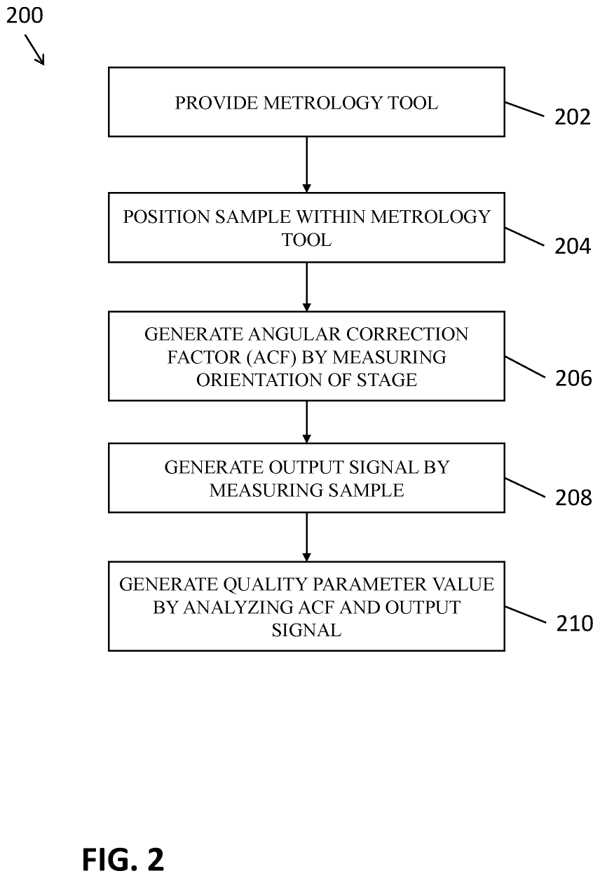

It is appreciated that the system and method described hereinbelow with reference to FIGS. 1A-2 are used to measure semiconductor devices and generate quality metrics therefor, such as indications of misregistration between different layers of semiconductor devices, and are part of a manufacturing process for semiconductor devices. The quality metrics generated by the system and method described hereinbelow with reference to FIGS. 1A-2 are used to adjust fabrication processes, such as lithography, during the manufacturing of semiconductor devices, to ameliorate the semiconductor devices being fabricated, for example, to ameliorate misregistration between various layers of semiconductor devices.

Values of many quality parameters of samples measured by metrology tools, such as, inter alia, feature dimensions and spatial registration of various layers formed on a substrate, are typically dependent on a rotational orientation of the sample during measurement by the metrology tool. Since samples are often positioned on a stage of the metrology tool during measurement, the values of the quality parameters are thus dependent on a rotational orientation of the stage, which can typically be positioned to have an intended rotational orientation.

However, ovalities in bearings that are in contact with the stage, thermal stress and part distortions can all contribute to an undesired angular shift in to the rotational orientation of the stage, which can adversely affect the quality parameter value output by the metrology tool. Moreover, in metrology tools having moving stages, the undesired angular shifts in the rotational orientation of the moving stage typically change with the motion of the stage, and are often not repeatable.

In conventional semiconductor misregistration metrology tools, undesired angular shifts in the stage of the metrology tool are typically accounted for by measuring misregistration of metrology targets having 180° rotational symmetry in a plane being generally parallel to an upper surface of the sample. However, metrology targets having 180° rotational symmetry typically include redundant features to allow output signals generated by measurements of the symmetric metrology target by the metrology tool to provide sufficient data for an accurate calculation of the quality parameter, regardless of the undesired angular shift of the stage supporting the sample during measurement. These redundant metrology features required dedicated space on the sample, reducing a number of functional features that can be formed on the sample.

Unlike conventional systems and methods, the systems and methods of present invention ascertain a rotational orientation of the stage of the metrology tool relative to other components of the metrology tool, including any undesired angular shift thereof. The rotational orientation of the stage is then used as a calibration factor by the systems and methods of present invention, together with an output signal from a measurement of the sample, to generate a quality parameter value associated with the sample.

A further advantage of the systems and methods of the present invention is that they do not rely on symmetry of metrology targets, thus allowing accurate quality parameter values to be calculated from measurements of metrology targets that are not rotationally symmetric, and thus do not require redundant rotationally symmetric features. Thus, the space required by metrology targets measured using the systems and methods of present invention may be significantly less than the space required by conventional rotationally symmetric metrology targets, thereby increasing the yield of functional devices formed on the sample. In an embodiment of the present invention, the space required by metrology targets measured using the systems and methods of present invention may be half the space required by conventional rotationally symmetric metrology targets.

Reference is now made to FIGS. 1A, 1B and 1C, which are simplified schematic diagrams of respective first, second and third operative orientations of an embodiment of a system 100 for generating an angular calibration factor (ACF). It is appreciated that, for ease of understanding, FIGS. 1A-1C are not drawn to scale.

As seen in FIGS. 1A-1C, system 100 can include a metrology tool 110, a quality parameter generator (QPG) 120 and an angle monitoring sub-system (AMSS) 130. It is appreciated that while in the embodiment shown in FIGS. 1A-1C, QPG 120 is drawn as separate from metrology tool 110, in an alternative embodiment of the present invention, QPG 120 may be included in metrology tool 110. Similarly, while in the embodiment of the present invention shown in FIGS. 1A-1C, AMSS 130 is included in metrology tool 110, and in another embodiment of the present invention, AMSS 130 may be separate from metrology tool 110.

Metrology tool 110 can include a stage 132 and a housing 134. Stage 132 can include a translatable stage assembly 142, on which is mounted a rotatable stage component 144. In one embodiment of the present invention, metrology tool 110 additionally incudes a bridge 146, on which is mounted a metrology head 148. Bridge 146 may be either fixed or movable, and metrology head 148 may be either fixedly or movably mounted on bridge 146.

A rotational orientation of metrology head 148 relative to housing 134 may be fixed, and thus a rotational orientation of stage 132 and portions thereof relative to metrology head 148 is the same as a rotational orientation of stage 132 and portions thereof relative to housing 134. Alternatively, a rotational orientation of metrology head 148 relative to housing 134 is known, and thus a rotational orientation of stage 132 and portions thereof relative to metrology head 148 is easily calculated from a rotational orientation of stage 132 and portions thereof relative to housing 134.

Metrology tool 110 may be any suitable metrology tool, including, inter alia, an imaging-based misregistration metrology tool, a scatterometry-based misregistration metrology tool, a critical dimension metrology tool, a shape metrology tool, a film metrology tool, an electron-beam metrology tool and an X-ray-based metrology tool, such as a layer-to-layer X-ray metrology tool. Exemplary metrology tools suitable for use as metrology tool 110 include, inter alia, an Archer™ 750, an ATL™ 100, a SpectraShape™ 11k, a SpectraFilm™ F1 and an eDR7380™ all of which are commercially available from KLA Corporation of Milpitas, Calif., USA. An additional exemplary metrology tool suitable for use as metrology tool 110 is an X-ray-based metrology tool similar to the X-ray-based metrology tool described in U.S. Pat. No. 9,778,213.

Metrology tool 110 can be operative to measure a quality metric of a sample, which can be embodied as a semiconductor device wafer (SDW) 150, such as a misregistration between at least two layers formed on SDW 150, a dimension of one or more features 152 formed on SDW 150 or a dimension of one or more spaces 154 between features 152 formed on SDW 150.

SDW 150 is typically generally disc-like in shape, and can include a positioning feature 156, such as a notch or a flattened portion. Positioning feature 156 is useful in identifying a rotational orientation of SDW 150 within an x-y plane, indicated in FIGS. 1A-1C by x- and y-axes, which is generally parallel to an upper surface 158 of SDW 150.

Features 152 may be formed with a single layer formed on SDW 150 or with multiple layers formed on SDW 150. For example, in the example shown in FIGS. 1A-1C, some features 152 are formed together with a first layer 166 formed on SDW 150 and other features 152 are formed together with a second layer 168 formed on SDW 150. As is known in the art, features on semiconductor device wafers are typically characterized by a smallest dimension thereof in the x-y plane, such as dimensions D₁ and D₂ of features 152 indicated in FIGS. 1A-1C. Similarly, spaces between features on semiconductor device wafers are typically characterized by a smallest dimension thereof in the x-y plane, such as dimensions D₃, D₄ and D₅ of spaces 154 indicated in FIGS. 1A-1C.

In one embodiment of the present invention, features 152 may together form a metrology target 170, such as a misregistration metrology target. In one embodiment of the present invention, metrology target 170 may be embodied as a conventional misregistration metrology target, having rotational symmetry. However, as described hereinabove, in an embodiment of the present invention, metrology target 170 is formed without redundant features typically included in conventional misregistration metrology targets, and thus does not exhibit rotational symmetry.

For simplicity, metrology target 170 is shown in FIGS. 1A-1C as being a portion of an advanced imaging metrology (AIM) target. However, metrology target 170 may form any suitable metrology target, such as, inter alia, a full or partial box-in-box target, such as a target similar to targets described in U.S. Pat. No. 7,804,994 or portions thereof; a full or partial AIM in-die (AIMid) target, such as a target similar to targets described in U.S. Pat. No. 10,527,951 or portions thereof; a full or partial blossom or micro-blossom target, such as a target similar to targets described in C. P. Ausschnitt, J. Morningstar, W. Muth, J. Schneider, R. J. Yerdon, L. A. Binns, N. P. Smith, “Multilayer overlay metrology,” Proc. SPIE 6152, Metrology, Inspection, and Process Control for Microlithography XX, 615210 (24 Mar. 2006) or portions thereof; a full or partial Moiré target, such as a target similar to targets described in U.S. Pat. No. 7,876,438 or portions thereof; a target useful in diffraction based measurements, such as a target similar to targets described in European Patent No. 1,570,232 or portions thereof; a target useful in electron-beam based measurements, such as a target similar to targets described in U.S. Pat. No. 7,608,468 or portions thereof; a hybrid imaging-electron beam target or a hybrid scatterometry electron-beam target, similar to targets described in PCT Application No. PCT/US2019/035282 or portions thereof; and a target useful in measuring misregistration between three or more layers, such as a target similar to targets described in U.S. Pat. No. 9,927,718 or portions thereof. Additionally, features 152 formed within metrology target 170 may include complete or partial semiconductor devices intended to be functional semiconductor devices, such as, inter alia, those described in PCT Application No. PCT/US2019/051209.

Stage 132 can be disposed within housing 134. In an embodiment of the present invention, translatable stage assembly 142 of stage 132 is operative to be moved linearly within the x-y plane, as indicated by a pair of directional arrows 172 and 174, and rotatable stage component 144 of stage 132 is operative to be rotated within the x-y plane, as indicated by a directional arrow 176. However, in some embodiments of the present invention, stage 132 and components thereof are either not intended to move linearly within the x-y plane or are not intended to rotate within the x-y plane. Similarly, in some embodiments of the present invention, stage 132 and components thereof are not intended to move linearly within the x-y plane and are not intended to rotate within the x-y plane.

Stage 132, particularly rotatable stage component 144, is operative to support and position a sample, such as SDW 150, being measured by metrology tool 110. Stage 132 may be any suitable stage, including, inter alia, a stage such as is described in PCT Application No. PCT/US2019/023918. The measurement orientation of SDW 150, including both a linear position of SDW 150 relative to housing 134 and a rotational orientation of SDW 150 relative to housing 134, is determined by a position of stage 132 and portions thereof. SDW 150 can be fixedly mounted on stage 132 during measurement, typically by a vacuum attachment, and the rotational orientation of SDW 150 in the x-y plane is determined by a corresponding rotational orientation of stage 132 and portions thereof.

As described hereinabove, stage 132 is characterized by a rotational orientation, which may include an undesired angular shift α of stage 132 relative to housing 134. FIG. 1A shows stage 132 in an ideal state, wherein there is no undesired angular shift of stage 132, and α=0. However, FIGS. 1B and 1C show more typical use cases, in which undesired angular shift α has a non-zero value, and stage 132 is rotatably shifted either clockwise relative to housing 134, as shown in FIG. 1B, or counterclockwise relative to housing 134, as shown in FIG. 1C. As mentioned hereinabove, FIGS. 1A-1C are not drawn to scale; in a typical use case, undesired angular shift α of stage 132 is too small to be detected by a human eye. As seen in FIGS. 1A-1C and as mentioned hereinabove, a sample, such as SDW 150, which is mounted on stage 132 during measurement by metrology tool 110 has a rotational orientation that is dependent on the rotational orientation of stage 132, including undesired angular shift α thereof.

System 100 can include AMSS 130 to measure the rotational orientation of stage 132 relative to housing 134, including undesired angular shift a, thereby generating the ACF. AMSS 130 can include a first radiation transmitter-receiver pair 182 and a second radiation transmitter-receiver pair 184. The radiation transmitted and received by each of first and second radiation transmitter-receiver pairs 182 and 184 may be laser light. An example of a radiation transmitter-receiver pair suitable as one or both of first and second radiation transmitter-receiver pairs 182 and 184 is a Sensor Head M12/C7.6, commercially available from attocube systems AG, of Haar, Germany. AMSS 130 can further include a radiation reflector 186, such as a generally planar mirror. An example of a mirror suitable as radiation reflector 186 is a plane mirror, commercially available from Renishaw, of Wotton-under-Edge, England.

In an embodiment of the present invention, as illustrated in FIGS. 1A-1C, first and second radiation transmitter-receiver pairs 182 and 184 are each fixedly mounted on translatable stage assembly 142 of stage 132, with a distance E therebetween. Radiation reflector 186 can be fixedly mounted on housing 134 in relatively close proximity to first and second radiation transmitter-receiver pairs 182 and 184, in the illustrated embodiment wherein first and second radiation transmitter-receiver pairs 182 and 184 are mounted on stage 132.

In an alternative embodiment of the present invention, first and second radiation transmitter-receiver pairs 182 and 184 are each fixedly mounted on housing 134, with a distance E therebetween, and radiation reflector 186 is fixedly mounted on translatable stage assembly 142 of stage 132 in relatively close proximity to first and second radiation transmitter-receiver pairs 182 and 184.

AMSS 130 can further include a calculator 192 for calculating a distance L₁ between first radiation transmitter-receiver pair 182 and radiation reflector 186, and a distance L₂ between second radiation transmitter-receiver pair 184 and radiation reflector 186. Calculator 192 also can calculate undesired angular shift α, using mathematical relationships, such as equation 1:

$$α = arctan ( \frac{{L}_{1} - {L}_{2}}{E} ) \qquad ( Eq . 1 )$$

In an embodiment of the present invention, distance E between first and second radiation transmitter-receiver pairs 182 and 184 is measured from a central portion of respective radiation beams emitted thereby, and is between 30-100 mm, such as 50 mm. Each of first and second radiation transmitter-receiver pairs 182 and 184 may be operative to measure distances L₁ and L₂, respectively, with an accuracy of +/−50 nm, and calculator 192 is operative to calculate undesired angular shift α, and thus the ACF, with an accuracy of 1 microradian.

It is appreciated that L₁ and L₂ represent respective perpendicular distances between first and second portions of stage 132 and housing 134, and need not represent paths traveled by radiation. Additionally, in one embodiment of the present invention, first and second radiation transmitter-receiver pairs 182 and 184 and radiation reflector 186 may be obviated, and replaced with a different suitable pair of distance-sensors, for example, mechanical linear motion encoders, such as, inter alia, encoders LIC 4100, commercially available from DR. JOHANNES HEIDENHAIN GmbH, of Traunreut, Germany. Such encoders can be operative to sense and generate an output indicating respective perpendicular distances between first and second portions of stage 132 and housing 134.

In an embodiment of the present invention, the value of undesired angular shift α calculated by calculator 192 is the ACF generated by AMSS 130 and provided to QPG 120. As seen in FIGS. 1A-1C, undesired angular shift α, and thus the ACF, may have any value, including a positive angle value, a negative angle value and a zero angle value.

It is appreciated that while calculator 192 is shown in FIGS. 1A-1C as being separate from both metrology tool 110 and QPG 120, calculator 192 may alternatively form part of either of metrology tool 110 and QPG 120. Additionally, AMSS 130 may include specialized components for laser displacement measurement, such as, inter alia, a Displacement Measuring Interferometer IDS3010, commercially available from attocube systems AG, of Haar, Germany.

QPG 120 can generate a quality parameter value of a sample, such as SDW 150, by analyzing the ACF provided by AMSS 130 and an output signal generated by metrology tool 110. In an embodiment wherein metrology tool 110 includes an optical metrology head 148, the output signal is typically generated by metrology tool 110 based on radiation, such as light, that is reflected or refracted by the sample toward metrology head 148. It is appreciated that the output signal is typically oriented within an x-y plane analogous to the x-y plane shown in FIGS. 1A-1C.

The quality parameter value may be related to any suitable parameter, such as, inter alia, a misregistration between at least first layer 166 and second layer 168; a dimension, such as D₁ or D₂, of at least one of features 152 in formed on SDW 150; a dimension, such as D₃, D₄ or D₅, of at least one of spaces 154 between features 152 on SDW 150; a shape of at least one of features 152 formed on SDW 150; and a shape of one of spaces 154 between features 152 formed on SDW 150.

QPG 120 and calculator 192 are coupled to components of the system 100. QPG 120 and calculator 192 can include a programmable processor, which is programmed in software and/or firmware to carry out the functions that are described herein, along with suitable digital and/or analog interfaces for connection to the other elements of system 100. Alternatively or additionally, QPG 120 and calculator 192 can include hard-wired and/or programmable hardware logic circuits, which carry out at least some of their functions. Although QPG 120 and calculator 192 are shown, for the sake of simplicity, as single, monolithic functional units, in practice the QPG 120 and calculator 192 may comprise multiple, interconnected control units, with suitable interfaces for receiving and outputting the signals that are illustrated in the figures and are described in the text. The QPG 120 and calculator 192 also can be part of the same unit. Program code or instructions for the QPG 120 and calculator 192 to implement various methods and functions disclosed herein may be stored in readable storage media, such as a memory in or associated with the QPG 120 and calculator 192 or other memory.

Reference is now made to FIG. 2, which is a simplified flowchart illustrating an embodiment of a method 200 for use with, inter alia, system 100 of FIGS. 1A-1C. It is appreciated that method 200 can be performed as part of a larger fabrication process of a sample, such as SDW 150, for example, after formation of at least one, and more typically of at least two, layers on the sample. Moreover, data generated as part of method 200 can be used to adjust fabrication parameters of the fabrication process of which method 200 forms a part.

As seen in FIG. 2, at a first step 202, a metrology tool, such as metrology tool 110, is provided. As described hereinabove with particular reference to FIGS. 1A-1C, the metrology tool can include a stage, such as stage 132, and a housing, such as housing 134. Additionally, the metrology tool can include, or is in communication with, an angle monitoring sub-system (AMSS), such as AMSS 130.

As described hereinabove, the metrology tool may be any suitable metrology tool, including, inter alia, an imaging-based misregistration metrology tool, a scatterometry-based misregistration metrology tool, a critical dimension metrology tool, a shape metrology tool, a film metrology tool, an electron-beam metrology tool and an X-ray-based metrology tool, such as a layer-to-layer X-ray metrology tool. Exemplary metrology tools suitable for use as the metrology tool of method 200 include, inter alia, an Archer™ 750, an ATL™ 100, a SpectraShape™ 11k, a SpectraFilm™ F1 and an eDR7380™, all of which are commercially available from KLA Corporation of Milpitas, Calif., USA. An additional exemplary metrology tool suitable for use as the metrology tool is an X-ray-based metrology tool similar to the X-ray-based metrology tool described in U.S. Pat. No. 9,778,213.

At a next step 204, the sample is positioned within the metrology tool of step 202. At step 204, the sample can be mounted on the stage, and the stage is moved relative to the housing to suitably position the sample for measurement by the metrology tool. It is appreciated that the movement of the stage at step 204 may include one or both of translating the stage linearly in either or both of the x and y directions and rotating the stage or components thereof within an x-y plane, as shown in FIGS. 1A-1C, which is generally parallel to an upper surface of the sample, such as upper surface 158 of SDW 150.

As described hereinabove, the rotational orientation of the stage may include undesired angular shift α, and thus the sample which is mounted on the stage during measurement by the metrology tool has a rotational orientation that is dependent on the rotational orientation of the stage, including undesired angular shift α thereof.

Therefore, at a next step 206, the rotational orientation of the stage and/or of a translatable stage assembly, such as translatable stage assembly 142, relative to the housing, including undesired angular shift α, is measured, and the ACF for both the stage and the sample is generated based on the rotational orientation.

In an embodiment of the present invention, the AMSS can calculate the rotational orientation of the stage indirectly. For example, as described hereinabove with reference to FIGS. 1A-1C, the AMSS can include at least two radiation transmitter-receiver pairs, such as first and second radiation transmitter-receiver pairs 182 and 184, which can be laser light transmitter-receiver pairs, and a radiation reflector, such as radiation reflector 186, for measuring respective linear distances L₁ and L₂ between a reference position, such as housing 134, and two different portions of the stage, which are separated by distance E.

Then, still at step 206, the AMSS can calculate the undesired angular shift α of the stage, using mathematical relationships, such as equation 1:

$$α = arctan ( \frac{{L}_{1} - {L}_{2}}{E} ) \qquad ( Eq . 1 )$$

Each of the radiation transmitter-receiver pairs can be operative to measure distances L₁ and L₂, respectively, with an accuracy of +/−50 nm, and the AMSS is operative to calculate undesired angular shift α, and thus the ACF, with an accuracy of 1 microradian.

In an alternative embodiment of the present invention, the AMSS measures the rotational orientation of the stage and/or of the translatable stage assembly, using any input from any suitable pairs of distance-sensors, for example, mechanical linear motion encoders, such as, inter alia, encoders LIC 4100, commercially available from DR. JOHANNES HEIDENHAIN GmbH, of Traunreut, Germany.

In an embodiment of the present invention, the ACF generated at step 206 is the value of undesired angular shift α. It is appreciated that as described hereinabove, undesired angular shift α, and thus the ACF generated at step 206, may have any value, including a positive angle value, a negative angle value and a zero angle value.

At a next step 208, the metrology tool of steps 202, 204 and 206 measures the sample positioned therein at step 204, thereby generating at least one output signal of the sample. It is appreciated that the sample can remain mounted on the stage during the measurement at step 208, and the rotational orientation of the stage at step 208 is the same as the rotational orientation of the stage at step 204.

In an embodiment of the present invention, the measurement at step 208 measures at least one rotationally asymmetric misregistration target, such as metrology target 170, formed on the sample, such as SDW 150.

At a next step 210, at least one quality parameter value of the sample measured at step 208 is generated, at least partially based on the ACF and the output signal generated at steps 206 and 208, respectively. The quality parameter generated at step 210 can be generated by a quality parameter generator (QPG), such as QPG 120. In an embodiment of the present invention, the quality parameter generated at step 210 is a misregistration between at least two layers formed on the sample a dimension of one or more features formed on the sample or a dimension of one or more spaces between the features formed on the sample. As described hereinabove, the quality parameter generated at step 210 can be used to adjust fabrication processes, such as lithography, to ameliorate the semiconductor devices being fabricated on the sample, for example, to ameliorate misregistration between various layers of semiconductor devices.

It will be appreciated by persons skilled in the art that the present invention is not limited to what has been particularly shown and described hereinabove. The scope of the present invention includes both combinations and subcombinations of various features described hereinabove as well as modifications thereof, all of which are not in the prior art.

1. A method of generating an angular calibration factor (ACF) for a metrology tool useful in a fabrication process, the method comprising:
providing said metrology tool, said metrology tool comprising:
a stage; and
a housing;
measuring a rotational orientation of said stage relative to said housing; and
generating said ACF for said stage based at least partially on said rotational orientation.

2. The method according to claim 1, further comprising:
positioning a sample within said metrology tool;
measuring said sample with said metrology tool thereby generating at least one output signal, said sample being mounted on said stage and said stage having said rotational orientation during said measuring; and
generating at least one quality parameter value of said sample at least partially based on said ACF and said output signal.

3. The method according to claim 2, wherein said positioning said sample within said metrology tool further comprises:
mounting said sample on said stage; and
moving said stage relative to said housing.

4. The method according to claim 2, wherein measuring said sample further comprises measuring at least one rotationally asymmetric misregistration target formed on said sample.

5. The method according to claim 2, wherein said quality parameter value is a misregistration between at least a first layer formed on said sample and a second layer formed on said sample.

6. The method according to claim 2, wherein said quality parameter value is a dimension of at least one feature formed on said sample.

7. The method according to claim 2, wherein said quality parameter value is a dimension of at least one space between features formed on said sample.

8. The method according to claim 1, wherein said measuring said rotational orientation of said stage relative to said housing further comprises:
measuring a first linear distance between a first portion of said stage and said housing;
measuring a second linear distance between a second portion of said stage and said housing; and
calculating said rotational orientation of said stage relative to said housing at least partially based on said first linear distance and said second linear distance.

9. A system for generating an angular calibration factor (ACF), the system comprising:
a metrology tool comprising:
a stage; and
a housing; and
an angle monitoring sub-system (AMSS) operative to measure a rotational orientation of said stage relative to said housing and to generate said ACF based at least partially on said rotational orientation.

10. The system according to claim 9, wherein said angle monitoring sub-system comprises:
at least two radiation transmitter-receiver pairs; and
at least one radiation reflector.

11. The system according to claim 10, wherein said radiation transmitter-receiver pairs transmit and receive laser light.

12. The system according to claim 10, wherein:
said radiation transmitter-receiver pairs are each fixedly mounted on said stage; and
said radiation reflector is fixedly mounted on said housing.

13. The system according to claim 10, wherein:
said radiation transmitter-receiver pairs are each fixedly mounted on said housing; and
said radiation reflector is fixedly mounted on said stage.

14. The system according to claim 9, wherein said angle monitoring sub-system comprises at least two encoders.

15. The system according to claim 9, wherein said stage is movable relative to said housing.

16. The system according to claim 9, wherein said metrology tool comprises one of:
an imaging-based misregistration metrology tool;
a scatterometry-based misregistration metrology tool;
a critical dimension metrology tool;
a shape metrology tool;
a film metrology tool;
an electron-beam metrology tool; or
an x-ray-based metrology tool.

17. The system according to claim 9, further comprising a quality parameter generator (QPG), wherein said AMSS provides said ACF to said QPG.

18. The system according to claim 17, wherein said QPG is operative to generate a quality parameter value of a sample based at least partially on said ACF and an output signal of said sample generated by said metrology tool.

19. The system according to claim 18, wherein said quality parameter value is a dimension of at least one feature formed on said sample.

20. The system according to claim 18, wherein said quality parameter value is a dimension of at least one space between features formed on said sample.

21. The system according to claim 18, wherein said quality parameter value is a misregistration between at least a first layer formed on said sample and a second layer formed on said sample.

22. The system according to claim 18, wherein said sample comprises a semiconductor device wafer.

23. A misregistration target useful in calculating a misregistration between at least a first layer formed on said sample and a second layer formed on said sample for use with the system of claim 9, said misregistration target being rotationally asymmetric.
